(19) United States
(12) Patent Application Publication
(10) Pub. No.: US 2026/0305023 A1
(43) Pub. Date: Oct. 1, 2026

(54) LIGHT SOURCE MODULE, LIGHTING SYSTEM AND LAMP

(71) Applicants: SUZHOU OPPLE LIGHTING CO., LTD., Suzhou City (CN); OPPLE LIGHTING CO., LTD., Shanghai (CN)

(72) Inventor: Changrong ZHU, Suzhou City (CN)

(73) Assignees: SUZHOU OPPLE LIGHTING CO., LTD., Suzhou City (CN); OPPLE LIGHTING CO., LTD., Shanghai (CN)

(21) Appl. No.: 19/686,623

(22) Filed: May 23, 2026

Related U.S. Application Data
(63) Continuation of application No. PCT/CN2024/133924, filed on Nov. 22, 2024.

(30) Foreign Application Priority Data
Nov. 23, 2023 (CN) 202311578641.0
Nov. 23, 2023 (CN) 202323178531.3

(51) Int. Cl. H10H 20/851; H05B 45/30; H10H 29/24

(52) U.S. Cl. CPC H10H 20/8512; H10H 29/24; H05B 45/30

(57) ABSTRACT

A light source module, a lighting system, and a lamp are provided. The light source module includes a first light-emitting unit, a second light-emitting unit, and a third light-emitting unit that are electrically independent of one another. The first light-emitting unit emits blue-green light, the second light-emitting unit emits yellow-green light, and the third light-emitting unit emits orange-red light. The emitted light of the first, second, and third light-emitting units is characterized by predetermined spectral distributions and chromaticity ranges. A driving circuit independently controls power supplied to the light-emitting units to adjust light output. White light generated by mixing light emitted from the light-emitting units may have an adjustable correlated color temperature and a low color deviation from a black body radiation locus. In some embodiments, the light source module further includes a fourth light-emitting unit configured to emit white light.

### CROSS-REFERENCE TO RELATED APPLICATIONS

This disclosure is based upon and claims the priority of PCT patent disclosure No. PCT/CN2024/133924 filed on Nov. 22, 2024, which claims priority to the Chinese patent disclosure No. 202311578641.0 filed on Nov. 23, 2023 and the Chinese patent disclosure No. 202323178531.3 filed on Nov. 23, 2023, the entire contents of which are hereby incorporated by reference herein for all purposes.

### TECHNICAL FIELD

The present disclosure relates to a light source module, a lighting system and a lamp.

### BACKGROUND

Among various light sources, Light Emitting Diodes (LEDs) are widely applied in various lighting devices such as indoor lighting and outdoor lighting, smart lighting, plant lighting, vehicle lighting, indoor display lighting and outdoor display lighting due to their low power consumption and high luminous efficiency.

### SUMMARY

The present disclosure provides a light source module, a lighting system, and a lamp.

According to one aspect, the light source module may include a first light-emitting unit, a second light-emitting unit, and a third light-emitting unit that are electrically independent of one another. The first light-emitting unit is configured to emit blue-green light, the second light-emitting unit is configured to emit yellow-green light, and the third light-emitting unit is configured to emit orange-red light. The light emitted by the first, second, and third light-emitting units is characterized by predetermined spectral distributions and chromaticity ranges.

According to another aspect, the present disclosure further provides a lighting system which may include the light source module and a driving circuit. The driving circuit is configured to independently control electrical power supplied to the light-emitting units, thereby enabling adjustment of the spectral output and white-light characteristics of the light source module.

The present disclosure further provides a lamp including the light source module and/or the lighting system.

It is to be understood that both the foregoing general description and the following detailed description are exemplary and explanatory only and are not restrictive of the present disclosure.

### BRIEF DESCRIPTION OF DRAWINGS

FIG. 1 is a schematic structural diagram of a light source module according to an example of the present disclosure;

FIG. 2 is a chromaticity point distribution diagram of a first light-emitting unit, a second light-emitting unit and a third light-emitting unit of the light source module on a CIE 1931 chromaticity diagram according to an example of the present disclosure;

FIG. 3 is a spectral energy distribution diagram of the first light-emitting unit, the second light-emitting unit, the third light-emitting unit and a fourth light-emitting unit of the light source module according to an example of the present disclosure;

FIG. 4A, FIG. 4B and FIG. 4C are spectral energy distribution diagrams of white light with different color temperatures mixed by light emitted by the first light-emitting unit, light emitted by the second light-emitting unit and light emitted by the third light-emitting unit of the light source module according to an example of the present disclosure;

FIG. 5A, FIG. 5B and FIG. 5C are spectral energy distribution diagrams of the light source module at different color temperatures when the fourth light-emitting unit of the light source module is selected as a 4000K white light source according to an example of the present disclosure;

FIG. 6A, FIG. 6B and FIG. 6C are spectral energy distribution diagrams of the light source module at different color temperatures when the fourth light-emitting unit of the light source module is selected as a 5000K white light source according to an example of the present disclosure;

FIG. 7A, FIG. 7B, FIG. 7C, FIG. 7D, FIG. 7E and FIG. 7F are schematic structural diagrams of packaging structures of a light source module according to other examples of the present disclosure;

FIG. 8 is a schematic structural diagram of a lighting system according to an example of the present disclosure;

FIG. 9 is a schematic structural diagram of a lamp according to an example of the present disclosure;

FIG. 10 is a schematic structural diagram of a light source module according to another example of the present disclosure;

FIG. 11 is an optical path diagram of a single lens in FIG. 10;

FIG. 12 is a diameter comparison diagram of each lens in FIG. 10.

### DETAILED DESCRIPTION

The light source module, the lighting system and the lamp provided by the present disclosure will be described in further detail below with reference to the accompanying drawings and examples.

Sometimes, for dimming and color tuning requirements, one solution adopts red-green-blue (RGB) three primary colors for color mixing. The LEDs used in such RGB color mixing are mainly composed of single-wavelength LED chips. In this case, the full-width half-maximum (FWHM) of each monochromatic spectrum is narrow, which cannot ensure a sufficient color rendering index, thus limiting the realization of desired white light.

In terms of color temperature adjustment, a dual-color temperature dimming method is commonly adopted, which realizes adjustable color temperature by mixing two white lights with different color temperatures. The adjustable color temperature range is limited. In addition, since the dimming locus is a straight line connecting two chromaticity coordinate points of the two color temperatures on the CIE 1931 chromaticity diagram, when adjusted to an intermediate color temperature, the light color deviates greatly from that of a standard light source at the same color temperature.

Furthermore, to further expand the overall color temperature range of white light, RGB three primary colors are usually superimposed on the basis of original single-color temperature or dual-color temperature white light for dimming and color tuning, i.e., RGBW or RGBCW multi-color mixing mode. The color mixing principle is as follows: when the target color temperature falls within the range of single-color temperature or dual-color temperature white light, the white light serves as the main body for color mixing; when the target color temperature exceeds the range, RGB three primary colors are mixed or compensation color is adopted to obtain white light with the target color temperature. In either way, the color rendering performance of the white light obtained by this type of color mixing can only be guaranteed within the color temperature range covered by the existing white light. When beyond this range, the LEDs adopted for the three primary colors are mainly composed of single-wavelength LED chips with narrow full-width half-maximum for each monochromatic light, resulting in poor spectral continuity of the mixed white light and failure to maintain a high color rendering index of the overall white light. With the improvement of people's living standards, the demand for lighting has become more diversified. It is urgent to provide a lighting device with wide color gamut and high light quality.

An example of the light source module of the present disclosure is a mixed-light LED packaged chip, and the packaging form may be PLCC surface mount packaging, ceramic surface mount packaging, CSP packaging, multi-in-one single surface mount packaging or COB chip integrated packaging, which is not limited in the present disclosure.

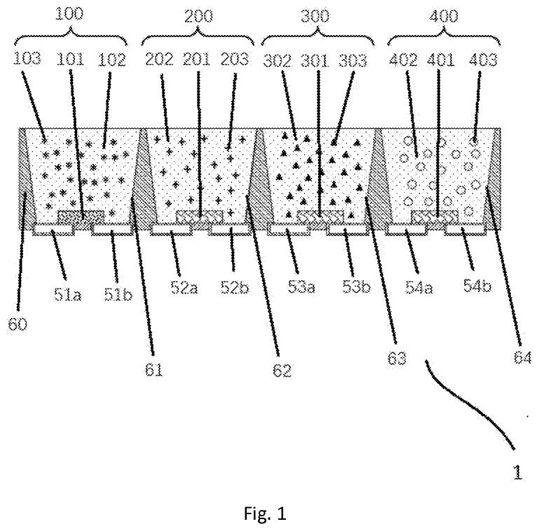

A structure of an example is shown in FIG. 1. The light source module 1 includes a main body portion 60 and a plurality of light-emitting units disposed on the main body portion 60 and spaced apart from each other, namely a first light-emitting unit 100, a second light-emitting unit 200, a third light-emitting unit 300 and a fourth light-emitting unit 400. Each light-emitting unit 100, 200, 300, 400 includes an LED chip 101, 201, 301, 401 accordingly and a packaging body 102, 202, 302, 402 covering the corresponding LED chip. The LED chip adopts forward mounting or flip-chip design, and a single LED chip or multiple LED chips can be connected in series, parallel or series-parallel combination. In this example, the main body portion 60 is a plastic bracket provided with a plurality of accommodating grooves 61, 62, 63, 64 to accommodate each packaging body 102, 202, 302, 402. The plastic bracket is made of any one of PPA, PCT and EMC materials. Each LED chip 101, 201, 301, 401 is disposed in the corresponding accommodating groove 61, 62, 63, 64 respectively and provided with a pair of pins 51a, 51b, 52a, 52b, 53a, 53b, 54a, 54b respectively, and each of the pins 51a, 51b, 52a, 52b, 53a, 53b, 54a, 54b are electrically isolated from each other. The packaging bodies 102, 202, 302, 402 are made of silicone resin, epoxy resin or a composite thereof, filled into the corresponding accommodating grooves 61, 62, 63, 64 and cover the corresponding LED chips 101, 201, 301, 401 to ensure electrical isolation between the light-emitting units 100, 200, 300, 400.

This example adopts a multi-light mixing solution, in which the first light-emitting unit 100 emits blue-green light, the second light-emitting unit 200 emits yellow-green light, and the third light-emitting unit 300 emits orange-red light, the combination of the blue-green light, the yellow-green light and the orange-red light can form white light, which is detailed as follows.

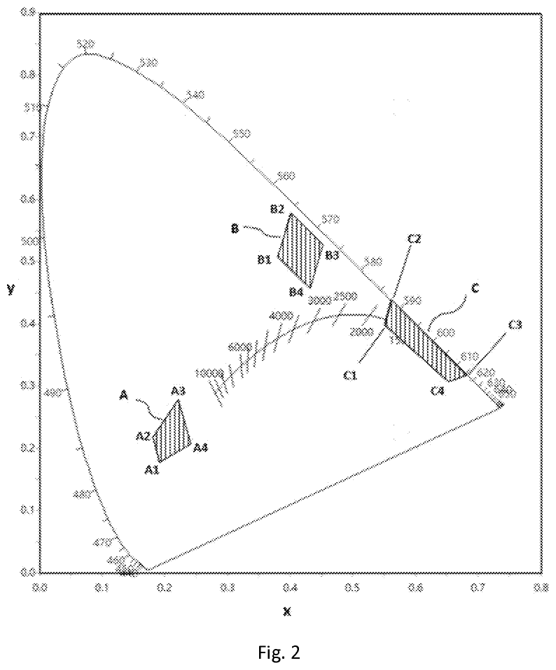

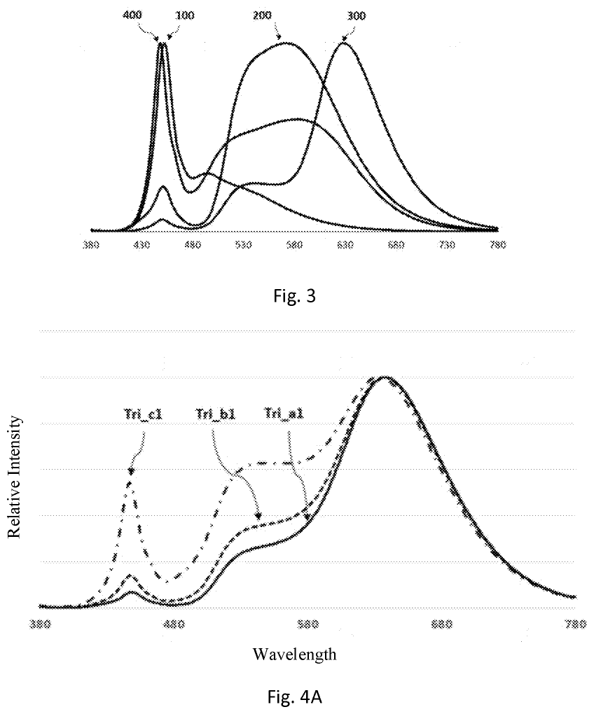

The first light-emitting unit 100 includes a first LED chip 101, a first packaging body 102 and a first phosphor. The first LED chip 101 is placed at a bottom of a first accommodating groove 61 and electrically connected to the outside via two pins 51a, 51b. The first packaging body 102 fills the first accommodating groove 61 and covers the first LED chip 101. The first LED chip 101 is a blue LED emitting blue light with a peak wavelength ranging from 450 nm to 465 nm. The first packaging body 102 contains a first phosphor 103, which at least includes one blue-green phosphor with a peak wavelength of 485 nm to 515 nm and at least one yellow-green phosphor with a peak wavelength of 520 nm to 580 nm. To achieve a wide FWHM, the first phosphor 103 contains both the blue-green phosphor and the yellow-green phosphor with different peak wavelengths. It should be noted that the blue-green phosphor and the yellow-green phosphor are not limited to a single chemical composition, and each of the blue-green phosphor and the yellow-green phosphor can be a mixed phosphor composed of multiple phosphor materials not a single phosphor to obtain the blue-green phosphor and the yellow-green phosphor which are required. The blue-green phosphor may be (Ba,Sr)Si₂N₂O₂:Eu. The yellow-green phosphor may be at least one selected from a group consisting of (Lu,Yb,Tb)₃(Al,Ga)₅O₁₂:Ce, Ga—Y₃Al₅O₁₂:Ce and Y₃(Al,Ga)₅O₁₂:Ce. After the first LED chip 101 excites the first phosphor 103, the spectral energy distribution of light emitted by the first light-emitting unit 100 is shown as curve 100 in FIG. 3. FIG. 3 is a relative spectral intensity diagram with normalized curves, where each point on the curve represents the energy magnitude at a corresponding wavelength on a horizontal axis. A wavelength of a dominant emission peak of light emitted by the first light-emitting unit 100 is 445 nm to 460 nm, a wavelength of a secondary emission peak of the light emitted by the first light-emitting unit is 480 nm to 500 nm, and peak energy of the secondary emission peak is 10% to 50% of peak energy of the dominant emission peak. A light color of the light emitted by the first light-emitting unit is blue-green light located in a quadrilateral region enclosed by four points A1(0.18,0.22), A2(0.22,0.28), A3(0.24,0.21) and A4(0.19,0.18) on a CIE 1931 chromaticity diagram i.e., region A marked in FIG. 2.

The second light-emitting unit 200 includes a second LED chip 201 and a second packaging body 202. The second LED chip 201 is placed at a bottom of the second accommodating groove 62 and electrically connected to the outside via two pins 52a, 52b. The second packaging body 202 fills the second accommodating groove 62 and covers the second LED chip 201. The second LED chip 201 is a blue LED emitting blue light with a peak wavelength of 445 nm to 455 nm. The second packaging body 202 contains a second phosphor 203 including at least one yellow-green phosphor, the yellow-green phosphor may be at least one selected from a group consisting of (Lu,Yb,Tb)₃(Al,Ga)₅O₁₂:Ce, Ga—Y₃Al₅O₁₂:Ce and Y₃(Al,Ga)₅O₁₂:Ce. After excitation by the second LED chip 201, the peak wavelength of light emitted by the second light-emitting unit 200 is 530 nm to 580 nm with a spectral half-width of 90 nm to 130 nm. The spectral half-width herein refers to the full-width half-maximum (FWHM) of an emission peak on a spectrogram. The spectral energy distribution is shown as curve 200 in FIG. 3. The light color of the light emitted by the second light-emitting unit 200 is yellow-green, located in the quadrilateral region enclosed by B1(0.38,0.51), B2(0.40,0.58), B3(0.45,0.53) and B4(0.43,0.46) on the CIE 1931 chromaticity diagram, i.e., region B marked in FIG. 2. Most of the energy emitted by the second LED chip 201 is converted into yellow-green light by the second phosphor 203, so that the blue light content of the second light-emitting unit 200 is lower than 30%. The blue light content lower than 30% means that the energy proportion of light in the blue band of 440 nm to 480 nm in the total luminous energy is less than 30%.

The third light-emitting unit 300 includes a third LED chip 301 and a third packaging body 302. The third LED chip 301 is placed at a bottom of the third accommodating groove 63 and electrically connected to the outside via two pins 53a, 53b. The third packaging body 302 fills the third accommodating groove 63 and covers the third LED chip 301. The third LED chip 301 is a blue LED emitting blue light with a peak wavelength of 445 nm to 455 nm. The third packaging body 302 contains a third phosphor 303 including at least one yellow-green phosphor with a peak wavelength of 520 nm to 580 nm and at least one red phosphor with a peak wavelength of 620 nm to 655 nm. The third phosphor 303 needs to contain both the yellow-green phosphor and the red phosphor. Each of the two types of phosphors may also be mixed phosphors. The yellow-green phosphor may be at least one selected from a group consisting of (Lu,Yb,Tb)₃(Al,Ga)₅O₁₂:Ce, Ga—Y₃Al₅O₁₂:Ce and Y₃(Al,Ga)₅O₁₂:Ce. The red phosphor may be at least one selected from a group consisting of CaAlSiN₃:Eu, (Ca,Sr)AlSiN₃:Eu, (Ba,Sr,Ca,Mg)₂Si₅N₈:Eu, K₂SiF₆:Mn⁴⁺, K₂GeF₆:Mn⁴⁺ and K₂TiF₆:Mn⁴⁺. After the third phosphor 303 is excited by the third LED chip 301, a wavelength of a dominant emission peak of light emitted by the third light-emitting unit is 620 nm to 655 nm, a wavelength of a secondary emission peak of the light emitted by the third light-emitting unit is 550 nm to 580 nm, and peak energy of the secondary emission peak is 0% to 40% of peak energy of the dominant emission peak, the spectral energy distribution is represented by curve 300 in FIG. 3. A light color of the light emitted by the third light-emitting unit is orange-red light located in a quadrilateral region enclosed by four points C1(0.55,0.40), C2(0.56,0.44), C3(0.68,0.32) and C4(0.65,0.31) on the CIE 1931 chromaticity diagram, that is, the region C marked in FIG. 2. Most of the energy emitted by the third LED chip 301 is converted into orange-red light by the third phosphor 303, so that the blue light content of the third light-emitting unit 300 is lower than 10%.

It can be seen from the above examples that although the first LED chip, the second LED chip and third LED chip are all blue chips, they adopt LEDs with different peak wavelengths. Phosphors usually have a wide FWHM distribution, while a monochromatic LED chip has a narrow FWHM. In this example, the first light-emitting unit 100 adopts blue-green phosphor, and part of blue light is not converted to maintain energy in the blue band, ensuring energy distribution at all wavelengths and excellent color rendering performance. In the blue light band, under the condition of narrow FWHM of LED chips, selecting chips with different peak wavelengths can form superposition in the blue band, making the overall energy distribution of the blue region more uniform and further improving the color rendering. In this example, two types of LED chips are selected: the first LED chip 101 is of the first type with a peak wavelength of 450 nm to 465 nm; the second LED chip 201 and the third LED chip 301 are of the second type with a peak wavelength of 445 nm to 455 nm. In alternative solutions, the peak wavelength difference between the two types of LED chips shall be greater than or equal to 5 nm. In other examples, the three LED chips of the first LED chip 101, the second LED chip 201 and the third LED chip 301 can have different peak wavelengths for a wider FWHM. However, since each LED chip in the light source module 1 is independently powered and controlled, excessive chip types may increase control complexity, which can be flexibly selected according to design requirements.

It is known that three primary colors can be mixed to form white light, and conventional solutions adopt RGB color mixing. This example optimizes the existing RGB solution by selecting different light colors: the first light-emitting unit emits blue-green light, the second light-emitting unit emits yellow-green light, and the third light-emitting unit emits orange-red light, and the mixed light of the blue-green light, the yellow-green light and the orange-red light can also form white light. By independently dimming and controlling the three light-emitting units, white light with different color temperatures can be mixed. In this example, PWM signals are adopted as control signals to independently control the three color light-emitting units, and different duty ratios are applied to adjust the luminous power of each light-emitting unit to achieve color mixing effects. Table 1 lists the PWM duty ratios of the three light-emitting units under different conditions, as well as the relative color temperature (CCT), the color deviation (Duv) and the color rendering index (CRI) after mixed.

TABLE 1

| | First | Second | Third | | | |
|---|---|---|---|---|---|---|
| | Light- | Light- | Light- | Relative Color | Color | Color |
| | Emitting | Emitting | Emitting | Temperature | Deviation | Rendering |
| Category | Unit 100 | Unit 200 | Unit 300 | CCT (k) | DUV | Index CRI |
| Tri_a1 | 0.7% | 2.7% | 96.6% | 1810 | 0.001 | 94.7 |
| Tri_b1 | 2.9% | 10.8% | 86.3% | 2121 | −0.001 | 94.7 |
| Tri_c1 | 12.5% | 25.5% | 62.1% | 2973 | 0.000 | 92.9 |
| Tri_d1 | 24.2% | 30.5% | 45.3% | 4005 | 0.000 | 91.3 |
| Tri_e1 | 42.2% | 28.6% | 29.2% | 6047 | −0.002 | 91.8 |
| Tri_f1 | 53.1% | 24.0% | 22.9% | 7992 | −0.001 | 91.2 |
| Tri_g1 | 64.3% | 17.4% | 18.3% | 11796 | 0.001 | 91.2 |
| Tri_h1 | 69.5% | 13.7% | 16.8% | 16362 | −0.002 | 94.2 |
| Tri_i1 | 72.5% | 11.4% | 16.1% | 19811 | −0.001 | 93.9 |

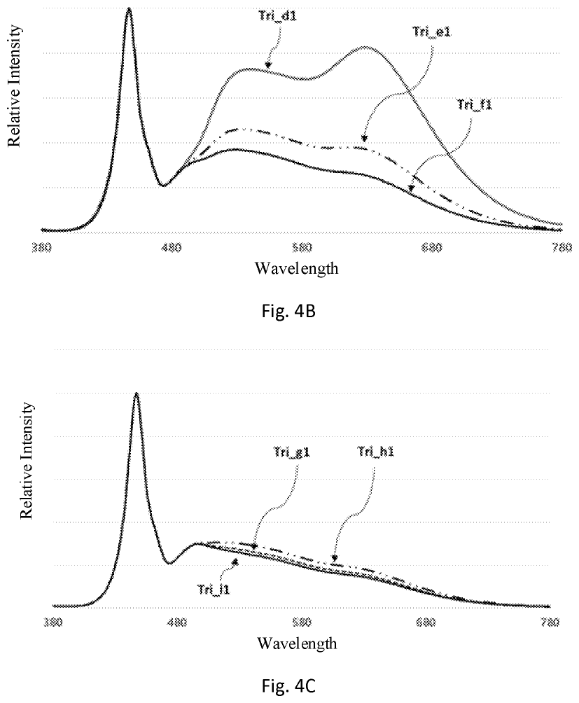

The relative spectra of white light in each category in Table 1 are shown in FIG. 4A, FIG. 4B and FIG. 4C. FIG. 4A corresponds to Tri_a1, Tri_b1 and Tri_c1; FIG. 4B corresponds to Tri_d1, Tri_e1 and Tri_f1; FIG. 4C corresponds to Tri_g1, Tri_h1 and Tri_i1. It can be seen from Table 1 that the white light mixed by the light emitted by the first light-emitting unit, the light emitted by the second light-emitting unit and the light emitted by the third light-emitting unit has a wide color temperature coverage range of 1800K to 20000K, the color deviation Duv from the black body radiation locus is less than 0.003, favorable color rendering performance can be achieved, and the color rendering index (CRI) at all color temperatures is greater than 90.

In the relationship between the relative color temperature and the color rendering index of the light source module 1 shown in Table 1, the color rendering index in the intermediate color temperature range can be further improved. As an example of the present disclosure, the light source module 1 adds a fourth light-emitting unit 400 on the basis of the first light-emitting unit, the second light-emitting unit and the third light-emitting unit to further optimize the overall light quality.

The fourth light-emitting unit 400 includes a fourth LED chip 401 and a fourth packaging body 402. The fourth LED chip 401 is placed at a bottom of the fourth accommodating groove 64 and electrically connected to the outside via two pins 54a, 54b. The fourth packaging body 402 fills the fourth accommodating groove 64 and covers the fourth LED chip 401. The fourth LED chip 401 is a blue LED emitting blue light with a peak wavelength of 445 nm to 455 nm. In this example, the fourth LED chip 401 adopts the same model as the second LED chip 201 and third LED chip 301, with a peak wavelength difference of 5 nm from the first LED chip 101. In other examples, other types of blue LED chips can be selected, which is not limited herein.

The fourth packaging body 402 contains a fourth phosphor 403. The fourth light-emitting unit 400 emits white light, so that the fourth phosphor 403 is mixed by multiple phosphors, the phosphors include at least one blue-green phosphor with a peak wavelength of 485 nm to 515 nm, at least one yellow-green phosphor with a peak wavelength of 520 nm to 580 nm, and at least one red-orange phosphor with a peak wavelength of 615 nm to 655 nm. In this example, the blue-green phosphor is (Ba,Sr)Si₂N₂O₂:Eu; the yellow-green phosphor may be at least one selected from a group consisting of (Lu,Yb,Tb)₃(Al,Ga)₅O₁₂:Ce, (Ba,Sr,Ca,Mg)SiO₄:Eu, Ga—Y₃Al₅O₁₂:Ce and Y₃(Al,Ga)₅O₁₂:Ce; the red-orange phosphor may be at least one selected from a group consisting of CaAlSiN₃:Eu, (Ca,Sr)AlSiN₃:Eu, (Ba,Sr,Ca,Mg)₂Si₅N₈:Eu, K₂SiF₆:Mn⁴⁺, K₂GeF₆:Mn⁴⁺ and K₂TiF₆:Mn⁴⁺. The fourth phosphor 403 is formed by mixing the above phosphors. After being excited by the fourth LED chip 401, the light emitted by the fourth light-emitting unit 400 is white light.

The first light-emitting unit, the second light-emitting unit and the third light-emitting unit can already form white light, and the added fourth light-emitting unit 400 is designed to possess distinctive characteristics. With the increasing demand for light quality, people pay more attention to the correlation between lighting and physiological rhythm. Studies have proved that different lighting environments are associated with melatonin secretion. Therefore, the fourth light-emitting unit 400 introduces the Melanopic Daylight Efficiency Ratio (MDER) index. By spectral compensation of specific bands, especially the cyan band and the yellow band, via the fourth light-emitting unit 400, the spectral continuity of the overall mixed white light is better.

MDER refers to the ratio of the equivalent melanopic illuminance of a light source to that under daylight (D65 standard light source). It is calculated by measuring the relative intensity of each wavelength and weighting with a specified formula to obtain the ratio of melanopic illuminance to photopic illuminance. The specific formula is as follows:

$$MDER = \frac{EDI\_mel ( D 65 )}{Ev} = 1.10385 \times \frac{{\int }_{380}^{780} P ( λ ) \cdot M ( λ ) \cdot d λ}{{\int }_{380}^{780} P ( λ ) \cdot V ( λ ) \cdot d λ}$$

Where:
EDI_mel(D65): Melanopic perceived illuminance equivalent to D65 standard light source;
Ev: Photopic perceived illuminance;
P(λ): Spectral power distribution of the tested light source;
V(λ): Photopic luminous efficiency function;
M(λ): Photosensitive function of intrinsically photosensitive retinal ganglion cells (ipRGC).

The above calculation formula complies with the parameter definition and calculation method issued by CIE S026.

In one solution, the fourth light-emitting unit 400 is selected as a white light chip with a relative color temperature of 4000±250K, CRI greater than 90 and MDER greater than 0.65. Similarly, PWM signals are adopted to independently control the four light-emitting units, and different duty ratios are applied to adjust the luminous power for color mixing effects. Table 2 lists the relative color temperature (CCT), the color deviation (Duv) and the color rendering index (CRI) of mixed light obtained by adjusting the duty cycle of PWM signals of four light-emitting units with the fourth light-emitting unit 400 incorporated.

TABLE 2

| | First | Second | Third | Fourth | | | |
|---|---|---|---|---|---|---|---|
| | Light- | Light- | Light- | Light- | Relative Color | Color | Color |
| | Emitting | Emitting | Emitting | Emitting | Temperature | Deviation | Rendering |
| Category | Unit 100 | Unit 200 | Unit 300 | Unit 300 | CCT (k) | DUV | Index CRI |
| For_a1 | 3.2% | 0.2% | 2.2% | 94.3% | 1812 | 0.000 | 94.6 |
| For_b1 | 9.3% | 0.5% | 8.7% | 81.5% | 2091 | 0.001 | 95.3 |
| For_c1 | 54.6% | 0.7% | 10.0% | 34.7% | 3033 | 0.001 | 96.8 |
| For_d1 | 83.8% | 3.7% | 5.7% | 6.8% | 4010 | 0.001 | 97.9 |
| For_e1 | 67.3% | 23.6% | 8.5% | 0.7% | 6031 | 0.000 | 95.7 |
| For_f1 | 56.2% | 36.1% | 7.6% | 0.1% | 7982 | 0.000 | 95.4 |
| For_g1 | 45.8% | 49.3% | 4.3% | 0.6% | 11961 | −0.001 | 95.6 |
| For_h1 | 33.8% | 57.9% | 4.3% | 4.0% | 15772 | −0.001 | 95.3 |
| For_i1 | 21.4% | 64.8% | 4.2% | 9.6% | 20211 | −0.002 | 95.8 |

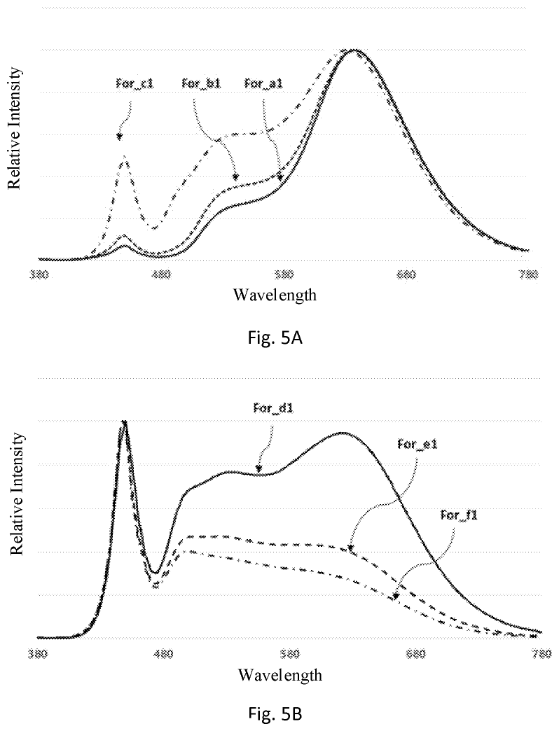

The relative spectrograms of white light in each category in Table 2 are shown in FIG. 5A, FIG. 5B and FIG. 5C. FIG. 5A corresponds to categories of For_a1, For_b1 and For_c1; FIG. 5B corresponds to categories of For_d1, For_e1 and For_f1; FIG. 5C corresponds to categories of For_g1, For_h1 and For_i1.

In another solution, the fourth light-emitting unit 400 can adopt a white light chip with the relative color temperature of 5000±250K, the color rendering index above 90 and the MDER exceeding 0.75. Similarly, PWM control signals are applied to independently regulate the four light-emitting units. Different duty cycles are set to adjust luminous power of each of the light-emitting units and achieve light mixing. Table 3 presents the relative color temperature (CCT), the color deviation (Duv) and the color rendering index (CRI) of mixed light obtained by adjusting the duty cycle of PWM signals of four light-emitting units with the fourth light-emitting unit 400 incorporated.

TABLE 3

| | First | Second | Third | Fourth | | | |
|---|---|---|---|---|---|---|---|
| | Light- | Light- | Light- | Light- | Relative Color | Color | Color |
| | Emitting | Emitting | Emitting | Emitting | Temperature | Deviation | Rendering |
| Category | Unit 100 | Unit 200 | Unit 300 | Unit 400 | CCT (k) | DUV | Index CRI |
| For_a2 | 1.0% | 0.2% | 2.8% | 96.0% | 1804 | 0.001 | 94.7 |
| For_b2 | 6.6% | 0.5% | 10.0% | 82.9% | 2113 | 0.001 | 95.2 |
| For_c2 | 39.3% | 0.3% | 14.2% | 46.2% | 3020 | −0.001 | 96.2 |
| For_d2 | 66.7% | 1.4% | 11.7% | 20.3% | 3997 | 0.001 | 98.1 |
| For_e2 | 78.0% | 13.8% | 4.6% | 3.6% | 5969 | −0.002 | 96.4 |
| For_f2 | 54.7% | 32.4% | 9.5% | 3.4% | 8035 | 0.001 | 96.2 |
| For_g2 | 47.9% | 45.6% | 5.1% | 1.4% | 12138 | 0.001 | 96.1 |
| For_h2 | 35.8% | 55.1% | 4.1% | 5.0% | 16101 | 0.000 | 96.1 |
| For_i2 | 23.4% | 62.5% | 4.7% | 9.4% | 19759 | −0.001 | 96.0 |

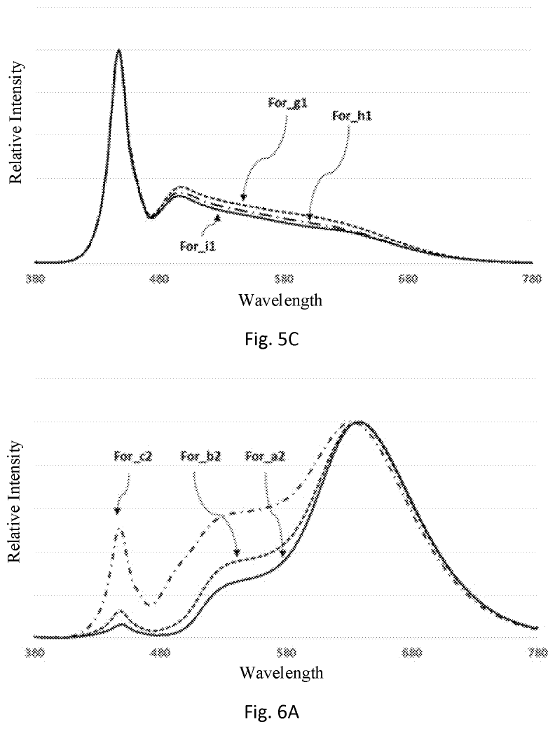

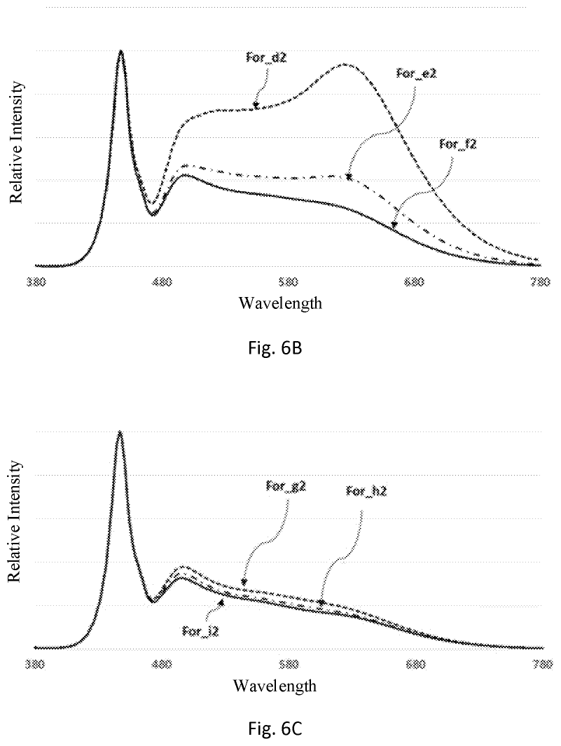

The relative spectrograms of white light in each category in Table 3 are shown in FIG. 6A, FIG. 6B and FIG. 6C. FIG. 6A corresponds to the categories of For_a2, For_b2 and For_c2, FIG. 6B corresponds to the categories of For_d2, For_e2 and For_f2, and FIG. 6C corresponds to the categories of For_g2, For_h2 and For_i2.

It can be seen from Table 2 and Table 3 that after adding the fourth light-emitting unit 400, the color rendering performance of the light source module 1 is further improved while maintaining the original color temperature range of white light of 1800K to 20000K. For the two types of the fourth light-emitting units 400, the CRI is above 95 within the color temperature range of 2100K to 20000K.

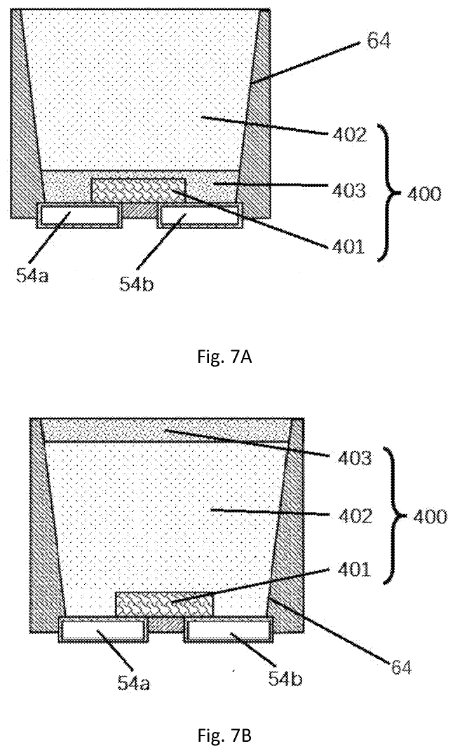

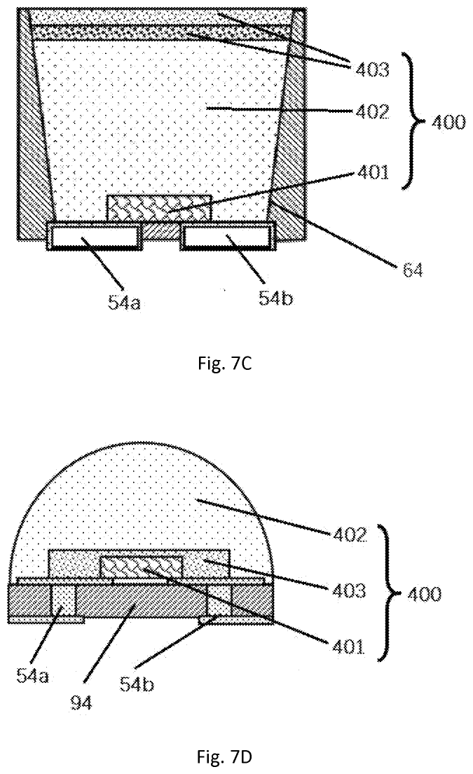

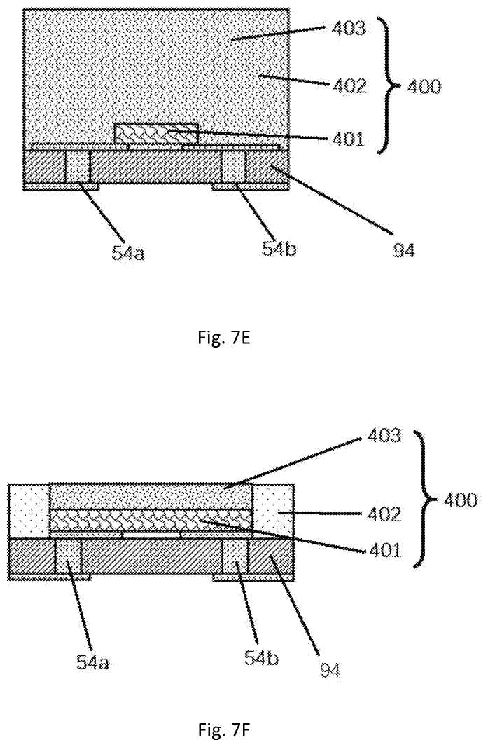

The example shown in FIG. 1 illustrates a packaging structure of the light source module 1, FIG. 1 shows an integrated packaging structure of the four light-emitting units. In other examples, each light-emitting unit can be independently packaged and then disposed on a same substrate to form the light source module 1, or packaged in groups of two, or the first light-emitting unit, the second light-emitting unit and the third light-emitting unit are integrally packaged while the fourth light-emitting unit is independently packaged, which is not limited herein. There are numerous available structures for individual packaging. Taking the fourth light-emitting unit 400 as an example, other packaging types are described below. The packaging structures in the examples of FIG. 7A and FIG. 7B adopt the bracket structure identical to that in FIG. 1, with accommodating grooves formed thereon. Only a single light-emitting unit of the light source module 1 is shown in the figure, that is the fourth light-emitting unit, and the accommodating groove is defined as the fourth accommodating groove 64. In the example of FIG. 7A, after the fourth LED chip 401 is placed, electrical connection with the outside is realized via pins 54a and 54b. The fourth phosphor 403 is evenly coated on the surface of the fourth LED chip 401 by spraying or dispensing, then the fourth packaging body 402 fills the fourth accommodating groove 64. In FIG. 7B, the fourth accommodating groove 64 pre-installed with the fourth LED chip 401 is first filled with the fourth packaging body 402, and the fourth phosphor 403 is subsequently spread on the top surface of the fourth packaging body 402 by spraying or dispensing. As aforementioned, the fourth phosphor 403 of the fourth light-emitting unit 400 contains multiple types of phosphors. Different from FIG. 7B, the packaging structure in FIG. 7C adopts layered coating of varied phosphors to form a double-layer structure as illustrated in the figure. FIG. 7D shows high-power ceramic packaging. A substrate 94 is made of ceramic or metal, with the fourth LED chip 401 arranged on the substrate 94. The fourth phosphor 403 forms a light conversion layer on the surface of the fourth LED chip 401 by spraying, phosphor film lamination or fluorescent ceramic sheet mounting. Afterwards, the fourth packaging body 402 is filled by mold injection molding to cover the fourth phosphor 403 and the fourth LED chip 401. FIG. 7E presents CSP packaging applicable to high-power chips. With ceramic or metal serving as the substrate 94, the fourth phosphor 403 is blended with the fourth packaging body 402 and the light conversion layer is formed on the surface of the fourth LED chip 401 by phosphor film lamination and complete encapsulation. FIG. 7F has a similar structure to FIG. 7E. A substrate 94 is made of ceramic or metal. The light conversion layer is formed on the surface of the fourth LED chip 401 by spraying, phosphor film lamination and the fourth packaging body 402 is disposed on the outer side of the light conversion layer to complete encapsulation. All the above methods can achieve the purpose of this application, and no limitation is made thereto.

Another example of the light source module of the present disclosure is shown in FIG. 10, the light source module includes a light source plate 6, four light-emitting units disposed on the light source plate, which are the first light-emitting unit 100, the second light-emitting unit 200, the third light-emitting unit 300 and the fourth light-emitting unit 400, and four lenses corresponding to the four light-emitting units one by one, which are the first lens 501, the second lens 502, the third lens 503 and the fourth lens 504. The first lens 501, the second lens 502, the third lens 503 and the fourth lens 504 cover the first light-emitting unit 100, the second light-emitting unit 200, the third light-emitting unit 300 and the fourth light-emitting unit 400 respectively. The spectrum and light color of the four units are consistent with those in the foregoing examples, which will be omitted herein.

It is known that the refractive index varies for colored light of different frequencies in the same medium. The lens in this example is made of PC material. The refractive index of light with a wavelength of 457.7 nm in PC is 1.60567, while the refractive index of light with a wavelength of 629.9 nm is 1.58071, indicating that the refractive index decreases as the wavelength increases. Hence, dedicated optical lenses shall be designed according to respective spectra. The spectrum of white light covers the full range from 380 nm to 780 nm, so calculations for white light are performed at the wavelength of 555 nm.

Referring to FIG. 4, in accordance with the refractive index law.

$$n 1 * sinθ1 = n 2 * sinθ2$$

$$and$$

$$n 2 * sinθ3 = n 3 * sinθ4 ;$$

n1=n3=1, n2 is the refractive index of different spectra.

θ1 is an incident angle of light emitted by the light source on the light incident surface 5051; θ2 is an exit angle of light exiting from the light incident surface 5051 and formed on the light incident surface 5051. The value of 01 is determined by an included angle between an incident light and a normal line of the incident surface. The curved surface of the light incident surface can be formed by rotating any free curve or conic curve (e.g., parabola, ellipse, circle). Differentiating based on the shape of the light incident surface can obtain the tangent equation, so as to obtain the normal equation, and the specific value of 01 can be calculated according to the incident light and a normal line, then according to n1*sin θ1=n2*sin θ2, θ2=arcsin (n2*sin θ2/sin θ1) can be obtained. The exit light from the light incident surface is also the incident light of the light exit surface 5052, and θ3=f(θ2) can be obtained through geometric relationship to get θ3. The exit angle θ4 is preset according to actual requirements. Given n2, θ3, n3 and θ4, a normal slope of the light exit surface can be calculated by the vector form of the refraction law, and the tangent slope can be obtained according to the perpendicular relationship between the normal line and the tangent line, so as to determine the curve of the light exit surface.

In this example, all lenses have the same light incident surface and the same final exit angle. According to the above calculation, the shorter the wavelength, the larger the refractive index and the smaller the size of the lens light exit surface, so lenses corresponding to different wavelengths have different sizes. As shown in FIG. 12, a diameter d1 of the first lens 501<a diameter d2 of the second lens 502<a diameter d4 of the fourth lens 504<a diameter d3 of the third lens 503. Therefore, the size of the third lens 503 covering red light is larger than that of the first lens 501 covering blue light. White light is calculated at 555 nm, so the size of the fourth lens 504 for white light is between the third lens 503 and the first lens 501. Specifically, the diameter d1 of the first lens 501 is 0.90~0.98 times the diameter d4 of the fourth lens 504; the diameter d2 of the second lens 502 is 0.95~1.00 times the diameter d4 of the fourth lens 504; the diameter d3 of the third lens 503 is 1.00~1.10 times the diameter d4 of the fourth lens 504.

In this example, the first lens 501, the second lens 502, the third lens 503 and the fourth lens 504 are integrated into one light distribution module 5. The fourth lens 504 is arranged at the center, with the other three lenses disposed around it. The centers of the first lens 501, the second lens 502 and the third lens 503 are evenly and angularly distributed on a circumference coaxial with the fourth lens.

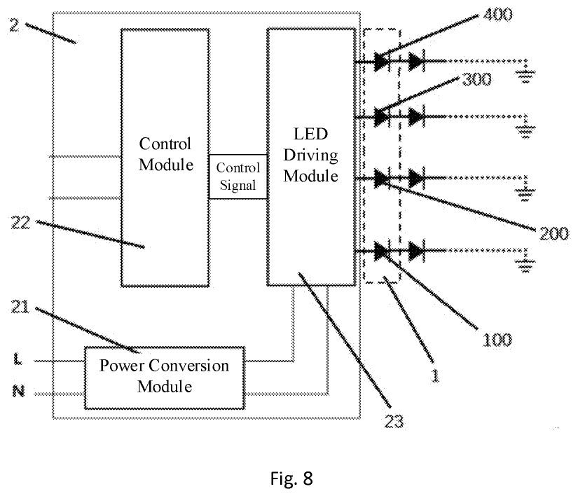

Another example of the present disclosure is the lighting system shown in FIG. 8, which includes the light source module 1 mentioned above and a driving circuit 2.

The driving circuit 2 comprises a power conversion module 21, a control module 22 and an LED driving module 23. The power conversion module 21 is connected to an external power supply and converts it into direct current power required by the light source module 1. The control module 22 includes a communication module that receives external dimming and color adjustment commands and generates corresponding control signals. The communication module can adopt wired or wireless communication mode, which is not limited herein. The LED driving module 23 receives DC power from the power conversion module 21 and control signals from the control module 22. It regulates the DC power according to the control signals, and outputs respective required driving current or voltage to the first light-emitting unit 100, the second light-emitting unit 200, the third light-emitting unit 300 and the fourth light-emitting unit 400 in the light source module 1. Accordingly, the LED driving module 23 is electrically connected to the first light-emitting unit 100, the second light-emitting unit 200, the third light-emitting unit 300 and the fourth light-emitting unit 400 respectively. When multiple light source modules 1 are arranged in the lighting system, as shown in FIG. 8, the first light-emitting unit 100, the second light-emitting unit 200, the third light-emitting unit 300 and the fourth light-emitting unit 400 of each light source module 1 are connected in series and then electrically coupled to the LED driving module 23.

As mentioned above, the color temperature of the light source module 1 in this example is adjustable within 1800K to 20000K. The control module 22 includes a storage module storing preset control parameter values, which correspond to the first light-emitting unit 100, the second light-emitting unit 200, the third light-emitting unit 300 and the fourth light-emitting unit 400 when the light source module 1 emits light at different color temperatures. The control parameters can be voltage values, current values or PWM signals. The parameter value is zero if the corresponding light-emitting unit does not participate in light mixing. Upon receiving an external color temperature adjustment command, the control module 22 reads relevant data from the storage module and transmits generated control signals to the LED driving module 23. The driving current and voltage output to the first light-emitting unit 100, the second light-emitting unit 200, the third light-emitting unit 300 and the fourth light-emitting unit 400 are adjusted to enable the light source module 1 to emit target colored light or white light with specified color temperature. In this example, the preset control parameters refer to the PWM duty cycles of each light-emitting unit listed in Table 1, Table 2 and Table 3. By adopting light-emitting units with specific colors and controlling them with preset parameters, the obtained white light has a broader color temperature range from 1800K to 20000K, with the chromatic deviation Duv from the black body radiation locus lower than 0.003. Meanwhile, the light source module possesses favorable color rendering capability. Its color rendering index CRI is above 90 within 1800K to 20000K, and exceeds 95 in the range of 2100K to 20000K. It delivers superior optical performance compared with conventional integrated RGB and RGBW light sources, and is highly applicable to general indoor lighting. In addition, multi-unit control enables colored light output. Diversified colored ambient light can be produced by adjusting the light output proportion of the first light-emitting unit, the second light-emitting unit, the third light-emitting unit and the fourth light-emitting unit, so as to build a colored lighting system.

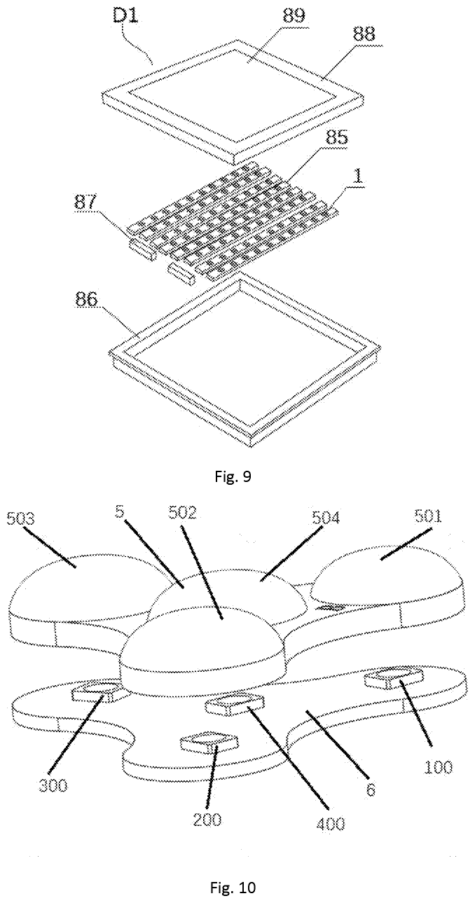

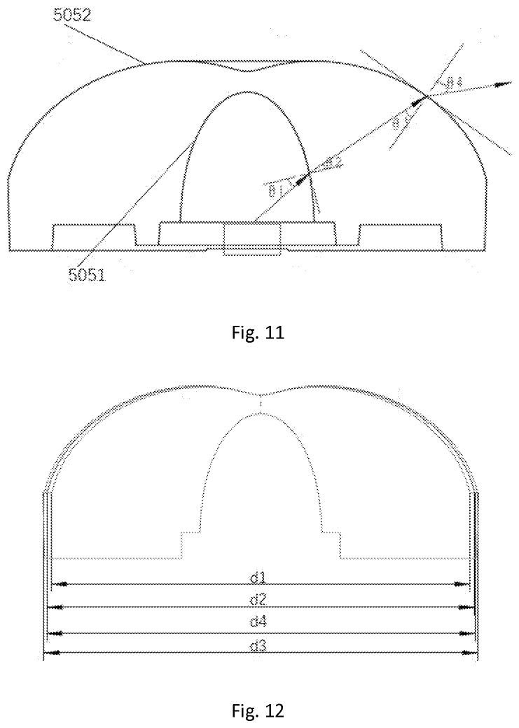

The above light source module and lighting system can be applied to various lamps. FIG. 9 shows a lamp D1 according to an example of the present disclosure, which is a light panel lamp including the aforesaid lighting system. In other examples, it can also be a chandelier, ceiling lamp, etc., and the light source module 1 can also be used as a conventional white light chip for table lamps, downlights, spotlights and other lamps. The lamp D1 includes a chassis 86, a frame 88 provided with a diffusion plate 89, a plurality of light source modules 1 disposed on a light source plate 85, and a power box 87, where the driving circuit 2 is disposed inside the power box 87. The lamp adopts separate wiring for the first light-emitting unit 100, the second light-emitting unit, the third light-emitting unit and the fourth light-emitting unit of the light source module 1; the same type of light-emitting units of each light source module 1 are connected in series and then connected to the driving circuit 2 in the power box 87 to form the aforesaid lighting system. The lamp D1 can also be equipped with a controller, heat dissipation device, light distribution components and the like according to functional requirements. The controller can adjust the light color and the intensity of the light emitted by the light source module L1; besides the diffusion plate in the example, the light distribution components can also be a lampshade, a lens, a diffusion element, a light guide and the like, which is not limited herein.

The present disclosure is intended to solve the above problems, and proposes a multi-color light source module, a lighting system and a lamp that can simultaneously achieve high-quality white light and color ambient light effects.

To achieve the above functions, the present disclosure adopts the following technical solution: a light source module includes a first light-emitting unit, a second light-emitting unit and a third light-emitting unit which are electrically independent of each other; the first light-emitting unit comprises a first light-emitting diode (LED) chip, a first packaging body covering the first LED chip and a first phosphor, a wavelength of a dominant emission peak of light emitted by the first light-emitting unit is 445 nm to 460 nm, a wavelength of a secondary emission peak of the light emitted by the first light-emitting unit is 480 nm to 500 nm, and peak intensity of the secondary emission peak is 10% to 50% of peak intensity of the dominant emission peak, a light color of the light emitted by the first light-emitting unit is blue-green light located in a quadrilateral region enclosed by four points A1(0.18,0.22), A2(0.22,0.28), A3(0.24,0.21) and A4(0.19,0.18) on a CIE 1931 chromaticity diagram; the second light-emitting unit comprises a second LED chip, a second packaging body covering the second LED chip and a second phosphor; a wavelength of a dominant emission peak of light emitted by the second light-emitting unit is 530 nm to 580 nm with a spectral half-width of 90 nm to 130 nm; a light color of the light emitted by the second light-emitting unit is yellow-green light located in a quadrilateral region enclosed by four points B1(0.38,0.51), B2(0.40,0.58), B3(0.45,0.53) and B4(0.43,0.46) on the CIE 1931 chromaticity diagram; the third light-emitting unit comprises a third LED chip, a third packaging body covering the third LED chip and a third phosphor, a wavelength of a dominant emission peak of light emitted by the third light-emitting unit is 620 nm to 655 nm, a wavelength of a secondary emission peak of the light emitted by the third light-emitting unit is 550 nm to 580 nm, and peak intensity of the secondary emission peak is 0% to 40% of peak intensity of the dominant emission peak, a light color of the light emitted by the third light-emitting unit is orange-red light located in a quadrilateral region enclosed by four points C1(0.55,0.40), C2(0.56,0.44), C3(0.68,0.32) and C4(0.65,0.31) on the CIE 1931 chromaticity diagram.

The present disclosure further provides a lighting system, which includes a light source and a driving circuit, the light source includes at least one of the light source modules as described above, the driving circuit is electrically connected to and supplies power to the first light-emitting unit, the second light-emitting unit and the third light-emitting unit respectively, and independently controls current/voltage supplied to each of the first light-emitting unit, the second light-emitting unit and the third light-emitting unit.

The present disclosure further provides a lamp, which includes the light source module or the lighting system mentioned above.

The light source module, the lighting system and the lamp provided by the present disclosure, by optimizing the light color of each monochromatic light-emitting unit, the light source module enables the mixed white light has a wide color temperature coverage ranging from 1800K to 20000K, and the light source module has an excellent color rendering performance with a color rendering index CRI greater than 90 within a color temperature range of 1800K to 20000K and the color rendering index CRI greater than 95 within the color temperature range of 2100K to 20000K. It achieves superior optical quality compared with conventional integrated light sources such as RGB and RGBW, making it more applicable to general indoor lighting. Meanwhile, multiple light-emitting units can be controlled to support colored light, forming a multi-color mixing system compatible with high-quality white light and colored ambient light.

The present disclosure may include dedicated hardware implementations such as disclosure specific integrated circuits, programmable logic arrays and other hardware devices. The hardware implementations can be constructed to implement one or more of the methods described herein. Examples that may include the apparatus and systems of various implementations can broadly include a variety of electronic and computing systems. One or more examples described herein may implement functions using two or more specific interconnected hardware modules or devices with related control and data signals that can be communicated between and through the modules, or as portions of an disclosure-specific integrated circuit. Accordingly, the system disclosed may encompass software, firmware, and hardware implementations. The terms “module,” “sub-module,” “circuit,” “sub-circuit,” “circuitry,” “sub-circuitry,” “unit,” or “sub-unit” may include memory (shared, dedicated, or group) that stores code or instructions that can be executed by one or more processors. The module refers herein may include one or more circuit with or without stored code or instructions. The module or circuit may include one or more components that are connected.

The foregoing description of the examples of the present disclosure is intended for illustration and description, rather than exhaustive or restrictive limitation to the specific disclosed forms.

1. A light source module, comprising: a first light-emitting unit, a second light-emitting unit and a third light-emitting unit which electrically independent from one another;
the first light-emitting unit comprises a first light-emitting diode (LED) chip, a first packaging body covering the first LED chip and a first phosphor, a wavelength of a dominant emission peak of light emitted by the first light-emitting unit is 445 nm to 460 nm, a wavelength of a secondary emission peak of the light emitted by the first light-emitting unit is 480 nm to 500 nm, and peak intensity of the secondary emission peak is 10% to 50% of peak intensity of the dominant emission peak, a light color of the light emitted by the first light-emitting unit is blue-green light located in a quadrilateral region enclosed by four points A1(0.18,0.22), A2(0.22,0.28), A3(0.24,0.21) and A4(0.19,0.18) on a CIE 1931 chromaticity diagram;
the second light-emitting unit comprises a second LED chip, a second packaging body covering the second LED chip and a second phosphor; a wavelength of a dominant emission peak of light emitted by the second light-emitting unit is 530 nm to 580 nm with a spectral half-width of 90 nm to 130 nm; a light color of the light emitted by the second light-emitting unit is yellow-green light located in a quadrilateral region enclosed by four points B1(0.38,0.51), B2(0.40,0.58), B3(0.45,0.53) and B4(0.43,0.46) on the CIE 1931 chromaticity diagram;
the third light-emitting unit comprises a third LED chip, a third packaging body covering the third LED chip and a third phosphor, a wavelength of a dominant emission peak of light emitted by the third light-emitting unit is 620 nm to 655 nm, a wavelength of a secondary emission peak of the light emitted by the third light-emitting unit is 550 nm to 580 nm, and peak intensity of the secondary emission peak is 0% to 40% of peak intensity of the dominant emission peak, a light color of the light emitted by the third light-emitting unit is orange-red light located in a quadrilateral region enclosed by four points C1(0.55,0.40), C2(0.56,0.44), C3(0.68,0.32) and C4(0.65,0.31) on the CIE 1931 chromaticity diagram.

2. The light source module according to claim 1, wherein a blue-light proportion of the second light-emitting unit is lower than 30%, and a blue-light proportion of the third light-emitting unit is lower than 10%.

3. The light source module according to claim 1, wherein the first LED chip, the second LED chip and the third LED chip at least include two types of LED chips, one with a peak wavelength of 450 nm to 465 nm and the other with a peak wavelength of 445 nm to 455 nm, and a peak wavelength difference between the two types of LED chips is greater than or equal to 5 nm.

4. The light source module according to claim 1, wherein the first phosphor at least comprises one blue-green phosphor with a peak wavelength of 485 nm to 515 nm and at least one yellow-green phosphor with a peak wavelength of 520 nm to 580 nm; the blue-green phosphor is (Ba,Sr)Si₂N₂O₂:Eu, and the yellow-green phosphor is at least one selected from a group consisting of (Lu,Yb,Tb)₃(Al,Ga)₅O₁₂:Ce, Ga—Y₃Al₅O₁₂:Ce and Y₃(Al,Ga)₅O₁₂:Ce.

5. The light source module according to claim 1, wherein the second phosphor comprises at least one yellow-green phosphor with a peak wavelength of 520 nm to 580 nm, which is at least one selected from a group consisting of (Lu,Yb,Tb)₃(Al,Ga)₅O₁₂:Ce, Ga—Y₃Al₅O₁₂:Ce and Y₃(Al,Ga)₅O₁₂:Ce.

6. The light source module according to claim 1, wherein the third phosphor at least comprises one yellow-green phosphor with a peak wavelength of 520 nm to 580 nm and at least one red phosphor with a peak wavelength of 620 nm to 655 nm; the yellow-green phosphor is at least one selected from a group consisting of (Lu,Yb,Tb)₃(Al,Ga)₅O₁₂:Ce, Ga—Y₃Al₅O₁₂:Ce and Y₃(Al,Ga)₅O₁₂:Ce; the red phosphor is at least one selected from a group consisting of CaAlSiN₃:Eu, (Ca,Sr)AlSiN₃:Eu, (Ba,Sr,Ca,Mg)₂Si₅N₈:Eu, K₂SiF₆:Mn⁴⁺, K₂GeF₆:Mn⁴⁺ and K₂TiF₆:Mn⁴⁺.

7. The light source module according to claim 1, wherein white light mixed by the light emitted by the first light-emitting unit, the light emitted by the second light-emitting unit and the light emitted by the third light-emitting unit has an adjustable color temperature ranging from 1800K to 20000K, and a color deviation (Duv) from a black body radiation locus is less than 0.003.

8. The light source module according to claim 7, wherein a color rendering index (CRI) of the white light generated from the light emitted by the first light-emitting unit, the light emitted by the second light-emitting unit and the light emitted by the third light-emitting unit is greater than 90 within the color temperature range of 1800K to 20000K.

9. The light source module according to claim 1, further comprising a fourth light-emitting unit, wherein the fourth light-emitting unit comprises a fourth LED chip, a fourth packaging body covering the fourth LED chip and a fourth phosphor, and the fourth light-emitting unit emits white light with a color temperature of 4000±250K, a color rendering index greater than 90 and a melanopic daylight efficiency ratio (MDER) greater than 0.65, or the color temperature of 5000±250K, the color rendering index greater than 90 and the melanopic daylight efficiency ratio (MDER) greater than 0.75.

10. The light source module according to claim 9, wherein the fourth phosphor comprises at least one blue-green phosphor with a peak wavelength of 485 nm to 515 nm, at least one yellow-green phosphor with a peak wavelength of 520 nm to 580 nm, and at least one red-orange phosphor with a peak wavelength of 615 nm to 655 nm, the blue-green phosphor is (Ba,Sr)Si₂N₂O₂:Eu; the yellow-green phosphor is at least one selected from a group consisting of (Lu,Yb,Tb)₃(Al,Ga)₅O₁₂:Ce, Ga—Y₃Al₅O₁₂:Ce, Y₃(Al,Ga)₅O₁₂:Ce and (Ba,Sr,Ca,Mg)SiO₄:Eu; the red-orange phosphor is at least one selected from a group consisting of CaAlSiN₃:Eu, (Ca,Sr)AlSiN₃:Eu, (Ba,Sr,Ca,Mg)₂Si₅N₈:Eu, K₂SiF₆:Mn⁴⁺, K₂GeF₆:Mn⁴⁺ and K₂TiF₆:Mn⁴⁺.

11. The light source module according to claim 9, wherein the light source module is a packaged chip comprising a main body portion provided with a first accommodating groove, a second accommodating groove, a third accommodating groove and a fourth accommodating groove, the first LED chip and the first phosphor are disposed in the first accommodating groove, the second LED chip and the second phosphor are disposed in the second accommodating groove, the third LED chip and the third phosphor are disposed in the third accommodating groove, and the fourth LED chip and the fourth phosphor are disposed in the fourth accommodating groove, the first packaging body, the second packaging body, the third packaging body and the fourth packaging body respectively fill the first accommodating groove, the second accommodating groove, the third accommodating groove and the fourth accommodating groove correspondingly, and the first packaging body, the second packaging body, the third packaging body and the fourth packaging body respectively cover the first LED chip, the second LED chip, the third LED chip and the fourth LED chip correspondingly.

12. The light source module according to claim 9, further comprising a light source plate, the first light-emitting unit, the second light-emitting unit, the third light-emitting unit and the fourth light-emitting unit are disposed on the light source plate, a first lens, a second lens, a third lens and a fourth lens are respectively arranged to cover the first light-emitting unit, the second light-emitting unit, the third light-emitting unit and the fourth light-emitting unit correspondingly; the first lens, the second lens, the third lens and the fourth lens are rotary lenses, and the first lens, the second lens, the third lens are uniformly distributed around the fourth lens along a circumference.

13. The light source module according to claim 9, wherein the color rendering index (CRI) of the white light emitted by the light source module is greater than 95 within the color temperature ranging from 2100K to 20000K.

14. A lighting system, comprising: a light source and a driving circuit;
the light source comprises at least one of the light source module that comprises:
a first light-emitting unit, a second light-emitting unit and a third light-emitting unit which electrically independent from one another;
the first light-emitting unit comprises a first light-emitting diode (LED) chip, a first packaging body covering the first LED chip and a first phosphor, a wavelength of a dominant emission peak of light emitted by the first light-emitting unit is 445 nm to 460 nm, a wavelength of a secondary emission peak of the light emitted by the first light-emitting unit is 480 nm to 500 nm, and peak intensity of the secondary emission peak is 10% to 50% of peak intensity of the dominant emission peak, a light color of the light emitted by the first light-emitting unit is blue-green light located in a quadrilateral region enclosed by four points A1(0.18,0.22), A2(0.22,0.28), A3(0.24,0.21) and A4(0.19,0.18) on a CIE 1931 chromaticity diagram;
the second light-emitting unit comprises a second LED chip, a second packaging body covering the second LED chip and a second phosphor; a wavelength of a dominant emission peak of light emitted by the second light-emitting unit is 530 nm to 580 nm with a spectral half-width of 90 nm to 130 nm; a light color of the light emitted by the second light-emitting unit is yellow-green light located in a quadrilateral region enclosed by four points B1(0.38,0.51), B2(0.40,0.58), B3(0.45,0.53) and B4(0.43,0.46) on the CIE 1931 chromaticity diagram;
the third light-emitting unit comprises a third LED chip, a third packaging body covering the third LED chip and a third phosphor, a wavelength of a dominant emission peak of light emitted by the third light-emitting unit is 620 nm to 655 nm, a wavelength of a secondary emission peak of the light emitted by the third light-emitting unit is 550 nm to 580 nm, and peak intensity of the secondary emission peak is 0% to 40% of peak intensity of the dominant emission peak, a light color of the light emitted by the third light-emitting unit is orange-red light located in a quadrilateral region enclosed by four points C1(0.55,0.40), C2(0.56,0.44), C3(0.68,0.32) and C4(0.65,0.31) on the CIE 1931 chromaticity diagram; and
the driving circuit is electrically connected to and supplies power to the first light-emitting unit, the second light-emitting unit and the third light-emitting unit respectively, and independently controls current/voltage supplied to each of the first light-emitting unit, the second light-emitting unit and the third light-emitting unit.

15. A lamp, comprising the light source module according to claim 1.

16. A lamp comprising the lighting system according to claim 14.
